(19) United States
(12) Patent Application Publication
(10) Pub. No.: US 2019/0179190 A1
(43) Pub. Date: Jun. 13, 2019

(54) FLEXIBLE LIQUID CRYSTAL DISPLAY

(71) Applicant: Chunghwa Picture Tubes, LTD., Taoyuan City (TW)

(72) Inventors: Chien-Hua Chen, Hsinchu County (TW); Jan-Tian Lian, Keelung City (TW); Chi-Ting Chiu, Yilan County (TW)

(73) Assignee: Chunghwa Picture Tubes, LTD., Taoyuan City (TW)

(21) Appl. No.: 15/893,712

(22) Filed: Feb. 12, 2018

(30) Foreign Application Priority Data
Dec. 12, 2017 (CN) 201711314917.9

(51) Int. Cl. G02F 1/1333; H01L 27/12; G02F 1/1334; G02F 1/1335

(52) U.S. Cl. CPC G02F 1/133305; H01L 27/1214; G02F 1/1334; G02F 1/1368; G02F 2201/501; G02F 1/133514; G02F 1/133512; G02F 1/133553

(57) ABSTRACT

A flexible liquid crystal display (LCD) is provided. The flexible LCD includes a first substrate, a second substrate, and a liquid crystal layer. The first substrate includes a first flexible substrate, a second flexible substrate, a reflective layer, and an active component layer. The second flexible substrate is disposed on the first flexible substrate. The reflective layer is disposed between the first flexible substrate and the second flexible substrate. The active component layer is disposed on the second flexible substrate. The second substrate is disposed on the first substrate. The liquid crystal layer is disposed between the first substrate and the second substrate. The substrate of the flexible LCD above has good strength and can block the laser from irradiating to the active component layer to prevent the damage of the active components of the active component layer.

### CROSS-REFERENCE TO RELATED APPLICATION

This application claims the priority benefit of China application serial no. 201711314917.9, filed on Dec. 12, 2017. The entirety of the above-mentioned patent application is hereby incorporated by reference herein and made a part of this specification.

### BACKGROUND

### 1. Field of the Invention

This disclosure is related to liquid crystal displays, especially related to flexible liquid crystal displays.

### 2. Description of Related Art

With the widespread use of portable displays, the development of flexible displays has become more active. Currently, flexible displays are mainly organic light-emitting diode (OLED) displays. However, compared with the liquid crystal displays (LCDs), manufacturing costs of OLED displays are high and moisture resistance thereof is poor, so various manufacturers are still committed to the development of flexible LCDs.

At present, most of the substrates used in LCD are glass-based. To meet flexible requirements, the substrate needs to be thinned to have a substantial degree of flexibility. However, the thinned substrate may be damaged due to the insufficient strength of the substrate during manufacturing, such as handling, cleaning, or the like.

Therefore, how to improve the substrate strength of a flexible LCD is one of the most pressing issues to be solved by current researchers.

### SUMMARY

A flexible liquid crystal display (LCD) is provided. The substrate of the flexible LCD has good strength and can block the laser from irradiating to the active component layer, thereby preventing the active components or circuits in the active component layer from being damage.

According to an embodiment of this invention, the flexible LCD comprises a first substrate, a second substrate, and a liquid crystal layer. The first substrate comprises a first flexible substrate, a second flexible substrate, a reflective layer, and an active component layer. The second flexible substrate is disposed on the first flexible substrate. The reflective layer is disposed between the first flexible substrate and the second flexible substrate. The active component layer is disposed on the second flexible substrate. The second substrate is disposed on the first substrate. The liquid crystal layer is disposed between the first substrate and the second substrate.

According to another embodiment of this invention, the first substrate further comprises a first barrier layer disposed between the second flexible substrate and the active component layer.

According to yet another embodiment of this invention, the second substrate comprises a third flexible substrate and a color filter pattern. The third flexible substrate is disposed on the liquid crystal layer. The color filter pattern is disposed between the third flexible substrate and the liquid crystal layer.

According to yet another embodiment of this invention, the second substrate further comprises a second barrier layer disposed between the third flexible substrate and the color filter pattern.

According to yet another embodiment of this invention, a material of the first barrier layer or the second barrier layer comprises silicon oxide, silicon nitride, or a combination thereof.

According to yet another embodiment of this invention, a material of the reflective layer comprises a metal, a metal compound, or a combination thereof.

According to yet another embodiment of this invention, the liquid crystal layer comprises polymer dispersed liquid crystal.

According to yet another embodiment of this invention, the flexible LCD further comprises a first polarizer and a second polarizer. The first polarizer is disposed on a surface of the first substrate away from the liquid crystal layer. The second polarizer is disposed on a surface of the second substrate away from the liquid crystal layer.

According to yet another embodiment of this invention, the active component layer comprises thin film transistors.

According to yet another embodiment of this invention, the flexible LCD is a reflective LCD.

In light of the foregoing, in the flexible LCD according to the above embodiments, the first substrate comprises the first flexible substrate, the second flexible substrate, and the reflective layer disposed therebetween to form a sandwich structure, thereby the strength of the first substrate can be increased. In addition, since the reflective layer is disposed between the first and second flexible substrates, when a laser is used to perform a release process to separate the carrier and the first flexible substrate, the laser can be blocked from irradiating to the active component layer, thereby preventing the active components or circuits in the active component layer from being damage.

The invention can be more fully understood by reading the following detailed description of the embodiment, with reference made to the accompanying drawings as follows.

### BRIEF DESCRIPTION OF THE DRAWINGS

The accompanying drawings are used to further understand this invention, and the drawings are incorporated herein to form a part of the specification. The drawings illustrate embodiments of the invention and, together with the description, serve to explain the principles of the invention.

FIG. 1 is a schematic cross-sectional view showing a flexible LCD according to an embodiment of this invention.

FIG. 2 is a schematic cross-sectional view showing a flexible LCD in a release process according to an embodiment of this invention.

FIG. 3 is a schematic cross-sectional view showing a flexible LCD according to another embodiment of this invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts. However, this invention may be practiced in many different forms and should not be construed to be limited to the embodiments.

The relative thicknesses and locations of layers, regions, and/or structures may be reduced or enlarged for clarity. In addition, in the drawings, similar or identical elements are used to represent similar or same elements or features. Therefore, the same reference numerals in the drawings denote the same elements and will not be redundantly described.

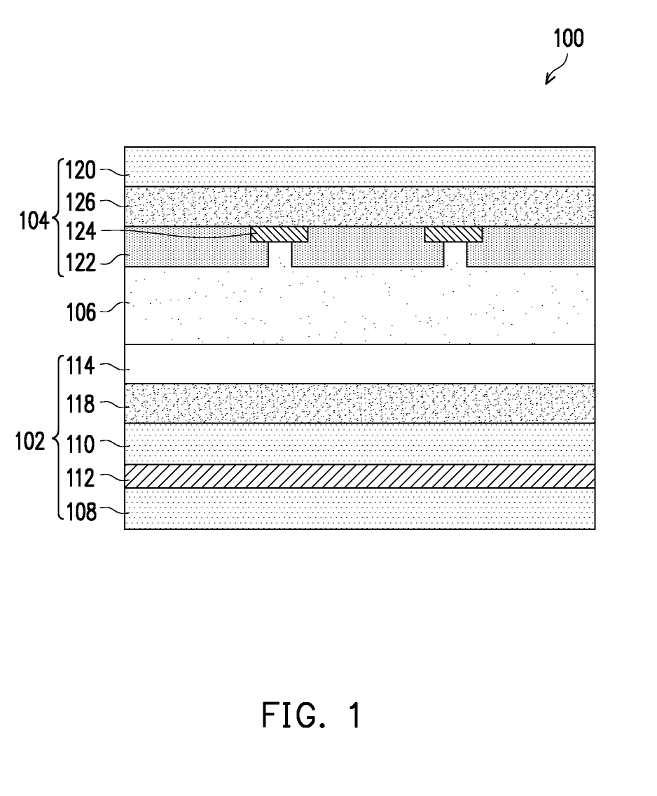

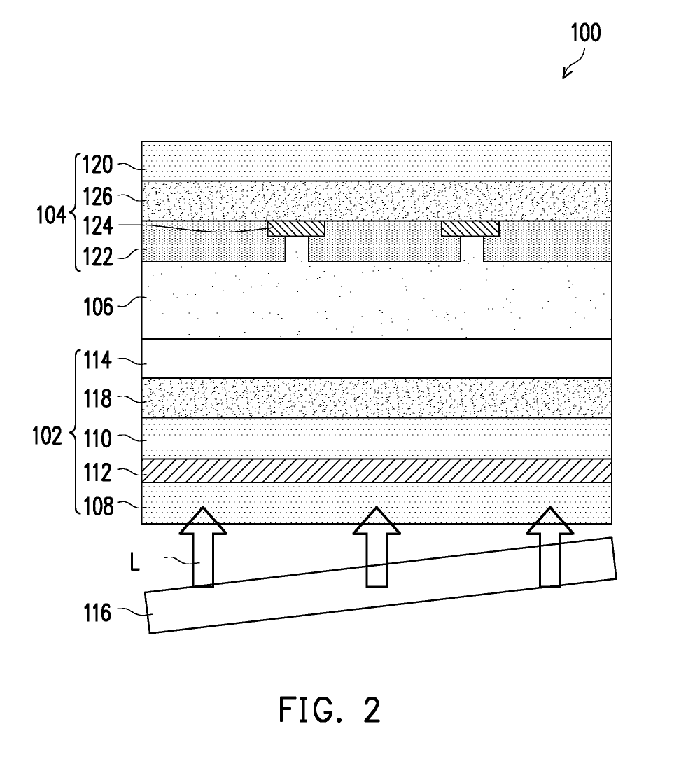

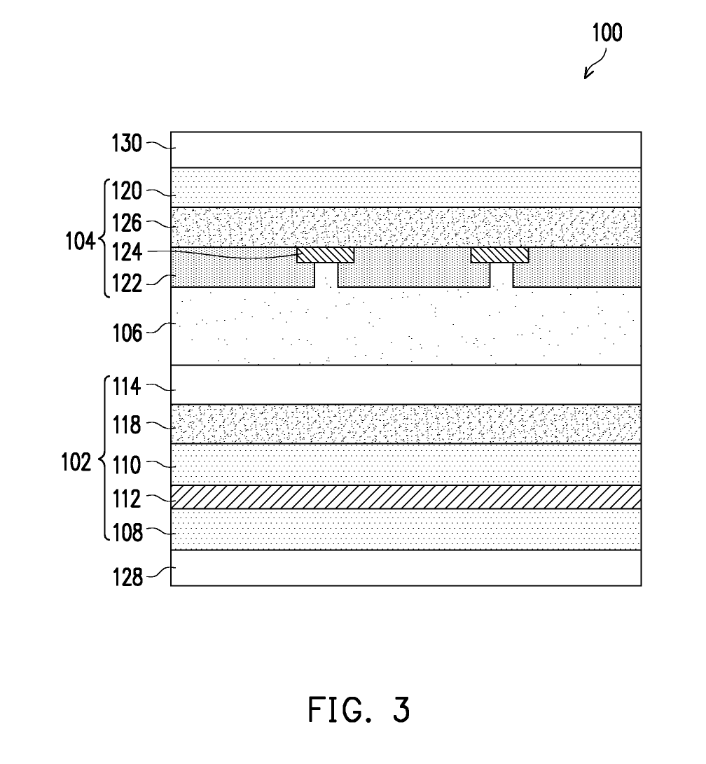

FIG. 1 is a schematic cross-sectional view showing a flexible LCD according to an embodiment of this invention. FIG. 2 is a schematic cross-sectional view showing a flexible LCD in a release process according to an embodiment of this invention. FIG. 3 is a schematic cross-sectional view showing a flexible LCD according to another embodiment of this invention.

Please refer to FIG. 1. A flexible LCD 100 comprises a first substrate 102, a second substrate 104, and a liquid crystal layer 106. In some embodiment, the flexible LCD 100 may be a reflective LCD, a transmissive LCD, or a trans-reflective LCD.

The first substrate 102 comprises a first flexible substrate 108, a second flexible substrate 110, a reflective layer 112, and an active component layer 114. In some embodiments, the first substrate 102 may be an active array substrate having switching elements, such as thin film transistors, for controlling the electro-optical property of the liquid crystal, scan lines for providing signals to the gates of the switching elements, data lines for providing signals to the drains of the switching elements, and common lines for connecting the drains and the pixel electrodes of the switching elements.

In this embodiment, a material of the first flexible substrate 108 may be polyimide (PI), but this invention is not limited thereto. In some other embodiments, the material of the first flexible substrate 108 may also be selected from a group consisting of polyethylene terephthalate (PET), polyethylene naphthalate (PEN), polycarbonate (PC), or poly(ether sulfones) (PES). Therefore, even if the thickness of the first flexible substrate 108 is thin, such as 10 μm, it does not cause damage during manufacturing, such as handling or cleaning.

The second flexible substrate 110 is disposed on the first flexible substrate 108. In this embodiment, a material of the second flexible substrate may be polyimide, but this invention is not limited thereto. In some other embodiments, the second flexible substrate 110 may also be selected from a group consisting of polyethylene terephthalate (PET), polyethylene naphthalate (PEN), polycarbonate (PC), or poly(ether sulfones) (PES). In some embodiments, the material of the second flexible substrate 110 may be the same as the first flexible substrate 108. The thickness of the second flexible substrate 110 may be the same as or different from the thickness of the first flexible substrate 108. In some embodiments, the thickness of the second flexible substrate 110 may be 10 μm.

The reflective layer 112 may be disposed between the first flexible substrate 108 and the second flexible substrate 110 to form a sandwich structure, thereby the strength of the first substrate 102 can be increased. Moreover, as shown in FIG. 2, when a laser L is used to perform a release process to separate the carrier 116 for carrying the first substrate 102 and the first flexible substrate 108, the reflective layer 112 can block the laser L from irradiating to the active component layer 114, thereby preventing the active components or circuits in the active component layer 114 from being damage. In some embodiments, a material of the reflective layer 112 may be a metal, a metal compound, or a combination thereof to further increase the strength of the first substrate 102 and the effect of protecting the active component layer 114 by increasing the blocking efficiency of the laser. For example, the material of the reflective layer 114 may be Au, Ag, Al, Mo, Ta, a metal compound of these metals, or any combinations thereof. In some other embodiments, the reflective layer 112 may also be a material with light-reflecting property. In some embodiments, the reflective layer 112 may be used to reflect environmental light. Therefore, no backlight modules are needed (i.e. a reflective LCD), so that the flexible LCD 100 has no problem of light leakage during bending. The thickness of the reflective layer 112 is 2 μm, for example. In some embodiments, the two opposite sides of the reflective layer 112 are respectively in direct contact with the first flexible substrate 108 and the second flexible substrate 110.

The active component layer 114 is disposed on the second flexible substrate 110. The component layer 114 may comprise thin film transistors (not shown), scan lines (not shown), data lines (not shown), common lines (not shown), common electrodes (not shown), and pixel electrodes (not shown). The scan lines and the data lines are interlaced and connected to the corresponding thin film transistors, respectively. The pixel electrodes are also connected to the corresponding thin film transistors. The common electrodes and the pixel electrodes may belong to the same layer or different layers. For example, when the flexible LCD 100 is an in-plane switching (IPS) LCD, the common electrodes and the pixel electrodes may belong to the same layer. When the flexible LCD 100 is a fringe field switching (FFS) LCD, the common electrode and the pixel electrode may belong to different layers.

In some embodiments, the first substrate 102 may further comprise a first barrier layer 118 disposed between the second flexible substrate 110 and the active component layer 114. Therefore, moisture and oxygen can be prevented from entering the active component layer 114 to improve the stability of the flexible LCD 100. In another aspect, since the first flexible substrate 108 and the second flexible substrate 110 are flexible substrates, and the reflective layer 112 located therebetween also has a considerable degree of flexibility (thinner thickness), the sandwich structure (the first flexible substrate 108/the reflective layer 112/the second flexible substrate 110) still has flexibility, resulting in a situation where the surface may have insufficient flatness. Based on this, when the first barrier layer 118 is disposed between the second flexible substrate 110 and the active component layer 114, the first barrier layer 118 may serve as a planarization layer to improve the flatness of the sandwich structure. So that the active component layer 114 on the stacked layer of the sandwich structure has better film-forming property. A material of the first barrier layer 118 may be an inorganic material, such as silicon oxide, silicon nitride, or a combination thereof.

The second substrate 104 is disposed on the first substrate 102. In this embodiment, the second substrate 104 is disposed on the side of the first substrate 102 adjacent to the active component layer 114. In this embodiment, the second substrate 104 may be a color filter substrate having a color filter pattern thereon, but the present invention is not limited thereto. In other embodiments, the color filter pattern can also be integrated on the first substrate 102, that is, a technique of integrating a color filter on a thin film transistor array (i.e. color filter on array, abbreviated as COA). In this embodiment, the second substrate 104 comprises a third flexible substrate 120 and a color filter pattern 122.

The third flexible substrate 120 is disposed on the first substrate 102. In this embodiment, a material of the third flexible substrate 120 may be polyimide, but this invention is not limited thereto. In some other embodiments, the material of the third flexible substrate 120 may also be selected from a group consisting of polyethylene terephthalate (PET), polyethylene naphthalate (PEN), polycarbonate (PC), or poly(ether sulfones) (PES). In some embodiments, the material of the third flexible substrate 120 may be the same as the first flexible substrate 108 or the second flexible substrate 110. The thickness of third flexible substrate 120 may be the same as or different from the thickness of the first flexible substrate 108 or the second flexible substrate 110. In some embodiments, the thickness of the third flexible substrate 120 may be 10 μm.

The color filter pattern 122 is disposed between the third flexible substrate 120 and the first substrate 102. The color filter pattern 122 may comprise a plurality of color filters of the same or different colors, which respectively correspond to the sub-pixels of the active component layer 114. A light shielding structure 124 may further comprise between two adjacent color filters to define a plurality of sub-pixel regions of the third flexible substrate 120. A material of the light shielding structure 124 may be a black matrix material, such as a metal chrome material or a black resin.

In some embodiments, the second substrate 104 may further comprise a second barrier layer 126 disposed between the third flexible substrate 120 and the color filter pattern 122 to block moisture and oxygen from the external environment, thereby enhancing the stability of the flexible LCD 100. On the other hand, since the third flexible substrate 120 has flexibility, the surface thereof may have insufficient flatness. Based on this, when the second barrier layer 126 is disposed between the third flexible substrate 120 and the color filter pattern 122. The second barrier layer 126 may also serve as a planarization layer to improve the flatness of the third flexible substrate 120, so that the color filter pattern 122 formed thereon has better film formability. The material of the second barrier layer 126 may be an inorganic material, such as silicon oxide, silicon nitride, or a combination thereof. A material of the second barrier layer 126 may be the same as or different from the material of the first barrier layer 118, and this invention is not limited thereto.

The liquid crystal layer 106 is disposed between the first substrate 102 and the second substrate 104. That is, in this embodiment, the third flexible substrate 120 of the second substrate 104 is disposed on the liquid crystal layer 106, and the color filter pattern 122 is disposed between the third flexible substrate 120 and the liquid crystal layer 106. In other embodiments, the color filter pattern 122 may also be disposed between the liquid crystal layer 106 and the active component layer 114 (for example, a technology of using COA). In this embodiment, the liquid crystal layer 106 may comprise polymer dispersed liquid crystal (PDLC), so that the liquid crystals in the liquid crystal cells are irregularly arranged when no driving voltage is applied, thereby the light cannot penetrate the liquid crystal layer 106; and the liquid crystals in the liquid crystal cells are arranged in a regular pattern when a driving voltage (for example, 5 V) is applied, so that the light can penetrate the liquid crystal layer 106. Accordingly, the flexible LCD 100 does not need any polarizer, and the second substrate 104 does not need to comprise any alignment structure layer, so that the flexible LCD 100 shows relatively high penetration, and the manufacturing cost of the flexible LCD 100 can be saved. In some embodiments, the polymer dispersed liquid crystal may be prepared by using nematic liquid crystals, a photopolymerizable material, and a photoinitiator. The photopolymerizable material may be a monomer or oligomer of an unsaturated thiol ester, an acrylic acid group-containing monomer or oligomer, or an epoxy group-containing monomer or oligomer, for example, but is not limited thereto. Specifically, a nematic liquid crystal, a photopolymerizable material, and a photoinitiator may be preliminarily mixed and subjected to an ultraviolet ray irradiation treatment to form a plurality of liquid crystal cell droplets. In other embodiments, the liquid crystal layer 106 may also adopt a liquid crystal material in which the liquid crystal molecules are arranged horizontally or vertically when no voltage is applied. However, it is necessary to add a polarizer. For example, as shown in FIG. 3, the flexible LCD 100 may further comprise a first polarizer 128 and a second polarizer 130. The first polarizer 128 is disposed on the surface of the first substrate 102 away from the liquid crystal layer 106, and the second polarizer is disposed on the surface of the second substrate away from the liquid crystal layer 106. In addition, when the liquid crystal layer 106 adopts a liquid crystal material in which the liquid crystal molecules are arranged horizontally when no voltage is applied, the transmittance of light is poor. Therefore, a backlight module (not shown) is also required to improve the brightness of the display. In some embodiments, the first substrate 102 and the second substrate 104 are in direct contact with the liquid crystal layer 106.

In light of the foregoing, in the flexible LCD, the first substrate comprises the first flexible substrate, the second flexible substrate, and the reflective layer between the first and the second flexible substrates to form a sandwich structure to increase the strength of the first substrate. In addition, since the reflective layer is disposed between the first and second flexible substrates, when a laser is used to perform a release process to separate the carrier and the first flexible substrate, the laser can be blocked from irradiating to the active component layer to prevent the damage of the active components or circuits of the active component layer.

Finally, it should be noted that the foregoing embodiments are merely intended for describing the technical solutions of the present invention, but not for limiting the present invention. Although the present invention has been described in detail with reference to the foregoing embodiments, those skilled in the art should understand that the technical solutions described in the foregoing embodiments may still be modified or replaced by equivalent to some or all of the technical features. These modifications or replacements do not make the essence of the corresponding technical solutions depart from the scope of the technical solutions of the embodiments in this invention.

1. A flexible liquid crystal display, comprising:
a first substrate, comprising:
a first flexible substrate;
a second flexible substrate disposed on the first flexible substrate;
a reflective layer disposed between the first flexible substrate and the second flexible substrate;
an active component layer disposed on the second flexible substrate; and
a first barrier layer disposed between the second flexible substrate and the active component layer;
a second substrate disposed on the first substrate; and
a liquid crystal layer disposed between the first substrate and the second substrate.

2. (canceled)

3. The flexible liquid crystal display of claim 1, wherein a material of the first barrier layer comprises silicon oxide, silicon nitride, or a combination thereof.

4. The flexible liquid crystal display of claim 1, wherein the second substrate comprises:
a third flexible substrate disposed on the liquid crystal layer; and
a color filter pattern disposed between the third flexible substrate and the liquid crystal layer.

5. The flexible liquid crystal display of claim 4, wherein the second substrate further comprises a second barrier layer disposed between the third flexible substrate and the color filter pattern.

6. The flexible liquid crystal display of claim 5, wherein a material of the second barrier layer comprises silicon oxide, silicon nitride, or a combination thereof.

7. The flexible liquid crystal display of claim 1, wherein a material of the reflective layer comprises a metal, a metal compound, or a combination thereof.

8. The flexible liquid crystal display of claim 1, wherein the liquid crystal layer comprises polymer dispersed liquid crystal.

9. The flexible liquid crystal display of claim 1, further comprising:
a first polarizer disposed on a surface of the first substrate away from the liquid crystal layer; and
a second polarizer disposed on a surface of the second substrate away from the liquid crystal layer.

10. The flexible liquid crystal display of claim 1, wherein the active component layer comprises thin film transistors.

11. The flexible liquid crystal display of claim 1, wherein the flexible liquid crystal display is a reflective liquid crystal display.
